(19) United States
(12) Patent Application Publication
(10) Pub. No.: US 2026/0344119 A1
(43) Pub. Date: Oct. 29, 2026

(54) LIGHT-EMITTING ELEMENT AND MANUFACTURING METHOD OF THE LIGHT-EMITTING ELEMENT

(71) Applicant: Japan Display Inc., Tokyo (JP)

(72) Inventor: Masumi NISHIMURA, Tokyo (JP)

(73) Assignee: Japan Display Inc., Tokyo (JP)

(21) Appl. No.: 19/716,624

(22) Filed: Jun. 23, 2026

Related U.S. Application Data
(63) Continuation of application No. PCT/JP2025/000021, filed on Jan. 6, 2025.

(30) Foreign Application Priority Data
Feb. 6, 2024 (JP) 2024-016176

(51) Int. Cl. H10H 20/816; H10H 20/01; H10H 20/817; H10H 20/825

(52) U.S. Cl. CPC H10H 20/816; H10H 20/0137; H10H 20/817; H10H 20/825

(57) ABSTRACT

A light-emitting element includes a hole-transporting layer, an electron-transporting layer, an emission layer, an anode, and a cathode. The emission layer is sandwiched by the hole-and electron-transporting layers. The anode and the cathode are electrically connected to the hole-transporting layer and the electron-transporting layer, respectively. The hole-transporting layer, the electron-transporting layer, and the emission layer include a compound semiconductor expressed by a formula of InₓAl_{y}Ga_{z}N. Here, x+y+z=1±0.05, 0<x<1, 0≤y<1, and 0≤z<1, whereas 0<z when y=0, and 0<y when z =0. In addition, at least one of the following relationships is satisfied: (1) y in the hole-and electron-transporting layers are each larger than y in the emission layer; and (2) z in the hole-and electron-transporting layers are smaller than z in the emission layer.

### CROSS-REFERENCE TO RELATED APPLICATIONS

This application is a Continuation of International Patent Application No. PCT/JP2025/000021, filed on Jan. 6, 2025, which claims the benefit of priority to Japanese Patent Application No. 2024-016176, filed on Feb. 6, 2024, the entire contents of which are incorporated herein by reference.

### FIELD

An embodiment of the present invention relates to a light-emitting element containing a compound semiconductor and a manufacturing method of the same.

### BACKGROUND

In recent years, inorganic light-emitting elements containing a nitride of a Group 13 element such as gallium nitride (GaN) and indium nitride (InN) as an active layer have been widely used. Although such inorganic light-emitting elements have been conventionally fabricated using a silicon substrate and a sapphire substrate, Japanese Patent Application Publications No. 2019-41113, 2018-168029, and 2000-124140 disclose that inorganic light-emitting elements can also be formed over a glass substrate, for example.

### SUMMARY

An embodiment of the present invention is a light-emitting element. The light-emitting element includes a hole-transporting layer, an electron-transporting layer, an emission layer, an anode, and a cathode. The emission layer is sandwiched by the hole-transporting layer and the electron-transporting layer. The anode and the cathode are electrically connected to the hole-transporting layer and the electron-transporting layer, respectively. The hole-transporting layer, the electron-transporting layer, and the emission layer each include a compound semiconductor expressed by a composition formula of InₓAl_{y}Ga_{z}N. Here, x+y+z=1±0.05, 0<x<1, 0≤y<1, and 0≤z<1, whereas 0<z when y=0, and 0<y when z=0. In addition, at least one of the following relationships is satisfied: (1) y in the hole-transporting layer and the electron-transporting layer are each larger than y in the emission layer; and (2) z in the hole-transporting layer and the electron-transporting layer are each smaller than z in the emission layer.

An embodiment of the present invention is a manufacturing method of a light-emitting element. The manufacturing method includes forming a hole-transporting layer, an electron-transporting layer, and an emission layer sandwiched by the hole-transporting layer and the electron-transporting layer with a sputtering method and forming an anode and a cathode electrically connected to the hole-transporting layer and the electron-transporting layer, respectively. The hole-transporting layer, the electron-transporting layer, and the emission layer each include a compound semiconductor expressed by a composition formula of InₓAl_{y}Ga_{z}N. Here, x+y+z=1±0.05, 0<x<1, 0≤y<1, and 0≤z<1, whereas 0<z when y=0, and 0<y when z=0. In addition, at least one of following relationships is satisfied: (1) y in the hole-transporting layer and the electron-transporting layer are each larger than y in the emission layer; and (2) z in the hole-transporting layer and the electron-transporting layer are each smaller than z in the emission layer.

An embodiment of the present invention is a display device. The display device includes a substrate and a plurality of pixels over the substrate. The plurality of pixels each includes a light-emitting element. The light-emitting element includes a hole-transporting layer, an electron-transporting layer, an emission layer, an anode, and a cathode. The emission layer is sandwiched by the hole-transporting layer and the electron-transporting layer. The anode and the cathode are electrically connected to the hole-transporting layer and the electron-transporting layer, respectively. The hole-transporting layer, the electron-transporting layer, and the emission layer each include a compound semiconductor expressed by a composition formula of InₓAl_{y}Ga_{z}N. Here, x+y+z=1±0.05, 0<x<1, 0≤y<1, and 0≤z<1, whereas 0<z when y=0, and 0<y when z=0. In addition, at least one of the following relationships is satisfied: (1) y in the hole-transporting layer and the electron-transporting layer are each larger than y in the emission layer; and (2) z in the hole-transporting layer and the electron-transporting layer are each smaller than z in the emission layer.

An embodiment of the present invention is a lighting device. The lighting device includes a substrate and a plurality of light sources over the substrate. The plurality of light sources each includes a light-emitting element. The light-emitting element includes a hole-transporting layer, an electron-transporting layer, an emission layer, an anode, and a cathode. The emission layer is sandwiched by the hole-transporting layer and the electron-transporting layer. The anode and the cathode are electrically connected to the hole-transporting layer and the electron-transporting layer, respectively. The hole-transporting layer, the electron-transporting layer, and the emission layer each include a compound semiconductor expressed by a composition formula of InₓAl_{y}Ga_{z}N. Here, x+y+z=1±0.05, 0<x<1, 0≤y<1, and 0≤z<1, whereas 0<z when y=0, and 0<y when z=0. In addition, at least one of the following relationships is satisfied: (1) y in the hole-transporting layer and the electron-transporting layer are each larger than y in the emission layer; and (2) z in the hole-transporting layer and the electron-transporting layer are each smaller than z in the emission layer.

### BRIEF DESCRIPTION OF DRAWINGS

FIG. 1A is a schematic cross-sectional view of a light-emitting element according to an embodiment of the present invention.

FIG. 1B is a schematic cross-sectional view of a light-emitting element according to an embodiment of the present invention.

FIG. 2 is a schematic cross-sectional view of an emission layer included in a light-emitting element according to an embodiment of the present invention.

FIG. 3 is a schematic top view of a display device according to an embodiment of the present invention.

FIG. 4 is a schematic cross-sectional view of a display device according to an embodiment of the present invention.

FIG. 5 is a schematic top view of a lighting device according to an embodiment of the present invention.

### DESCRIPTION OF EMBODIMENTS

Hereinafter, each embodiment of the present invention is explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted. The reference number is used when plural structures which are the same as or similar to each other are collectively represented, while a hyphen and a natural number are further used when these structures are independently represented.

In the specification and the claims, an expression “a structure is exposed from another structure” means a mode in which a part of the structure is not covered by the other structure and includes a mode where the part uncovered by the other structure is further covered by another structure.

In the specification and the claims, an expression that “a structure is exposed from another structure” means a state where a portion of the structure is not covered by the other structure and also includes a state where the portion which is not covered by the other structure is covered with another structure. Here, the vertical relationship between the structure and the other structure is irrelevant. In addition, the state expressed by this expression includes a state where the structure is not in contact with the other structure.

### First Embodiment

In the present embodiment, a light-emitting element according to an embodiment of the present invention is explained. This light-emitting element is an inorganic light-emitting element including a compound semiconductor containing a Group 13 element and a Group 15 element.

### 1. Structure

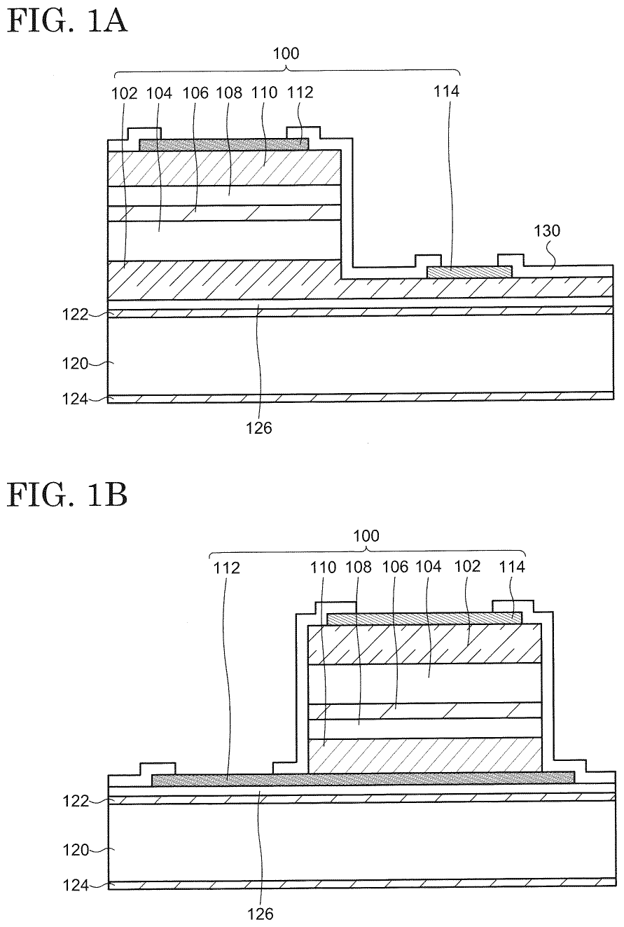

A schematic cross-sectional view of a light-emitting element 100 according to an embodiment of the present invention is shown in FIG. 1A. As shown in FIG. 1A, the light-emitting element 100 is formed over a substrate 120 and has an electron-transporting layer 104, a hole-transporting layer 108, and an emission layer 106 sandwiched between the electron-transporting layer 104 and the hole-transporting layer 108. The light-emitting element 100 further includes a cathode 114 and an anode 112 electrically connected to the electron-transporting layer 104 and the hole-transporting layer 108, respectively. The light-emitting element 100 may further have a hole-injection layer 110 between the anode 112 and the hole-transporting layer 108 and an electron-injection layer 102 between the cathode 114 and the electron-transporting layer 104. The electron-injection layer 102, the electron-transporting layer 104, the emission layer 106, the hole-transporting layer 108, and the hole-injection layer 110 may each have a single layer structure or may include a plurality of layers. For example, the emission layer 106 may have a so-called quantum well structure. A quantum well structure is a structure in which a plurality of layers with different band gaps and thicknesses of several nm are alternately stacked. Holes and electrons are injected from the anode 112 and cathode 114, respectively, when a potential difference equal to or greater than the emission threshold voltage is applied between the anode 112 and cathode 114, and the holes and the electrons are recombined in the emission layer 106 to produce light emission.

In the example shown in FIG. 1A, the electron-injection layer 102, the electron-transporting layer 104, the emission layer 106, the hole-transporting layer 108, and the hole-injection layer 110 are stacked in order from the substrate 120 side with a portion of the electron-injection layer 102 exposed from the electron-transporting layer 104, whereas the cathode 114 is provided over the exposed portion. However, the configuration of the light-emitting element 100 is not limited thereto, and the hole-injection layer 110, the hole-transporting layer 108, the emission layer 106, the electron-transporting layer 104, the electron-injection layer 102, and the cathode 114 may be stacked in order from the side of the anode 112 provided over the substrate 120 as shown in FIG. 1B, for example.

Hereinafter, each component is explained.

### (1) Substrate

The substrate 120 is a component to support the light-emitting element 100 provided thereover. There are no particular restrictions on the material included in the substrate 120, and the material thereof may be, for example, quartz, single crystal silicon, single crystal germanium, single crystal sapphire, amorphous glass, or a polymer such as a polyimide, a polyamide, and a polycarbonate. The substrate 120 may have a thickness sufficient to have flexibility (e.g., equal to or greater than 0.1 mm and equal to or less than 0.5 mm) or a greater thickness (e.g., equal to or greater than 0.5 mm and equal to or less than 2 mm).

When using an amorphous glass substrate as the substrate 120, it is preferable to use a substrate with a high strain point and high surface flatness. For example, an alkali-free glass substrate with a strain point of 600° C. or higher may be used as the substrate 120. In this case, the substrate 120 contains silicon dioxide, aluminum oxide, boron oxide, and an alkaline earth metal oxide such as calcium oxide and barium oxide. The content of an alkali metal such as sodium in the substrate 120 is preferred to be equal to or less than 0.1%. There is also no restriction on the size of the glass substrate, and, for example, a large rectangular amorphous glass substrate also known as mother glass may be used as the substrate 120. Specifically, a glass substrate having a size of 2160 mm×2460 mm and called 8th generation mother glass, a glass substrate having a size of 2400 mm×2800 mm and called 9th generation mother glass, a glass substrate having a size of 2880 mm×3130 mm and called 10th generation mother glass, or an even larger glass substrate may be used.

### (2) Electron-Injection Layer, Electron-Transporting Layer, Emission Layer, Hole-Transporting Layer, and Hole-Injection Layer

The electron-injection layer 102, the electron-transporting layer 104, the emission layer 106, the hole-transporting layer 108, and the hole-injection layer 110 (hereinafter, these layers may be referred to as functional layers) each include an indium-containing compound semiconductor. More specifically, these functional layers each include a compound semiconductor represented by a composition formula of InₓAl_{y}Ga_{z}N. Here, x+y+z=1±0.05, 0<x<1, 0≤y<1, and 0≤z<1. Moreover, 0<z when y=0, and 0<y when z=0. In view of the stoichiometry, x+y+z is 1. However, the composition of a compound semiconductor does not always agree with the stoichiometry one, and measurements always include errors. Therefore, the summation of x, y, and z is allowed to be up to 1±0.05. Since 0<x<1, all of the functional layers contain In along with nitrogen. In addition, since 0<z when y=0 and 0<y when z=0, each functional layer contains at least one of Al and Ga in addition to In and nitrogen. The composition of each functional layer may be determined using, for example, secondary ion mass spectrometry (SIMS), X-ray photoelectron spectroscopy (XPS), or energy dispersive spectroscopy (EDS). The electron-injection layer 102 and the electron-transporting layer 104 may further contain an n-type dopant such as silicon and germanium. Similarly, the hole-injection layer 110 and the hole-transporting layer 108 may contain a p-type dopant such as magnesium, zinc, cadmium, and beryllium.

Furthermore, at least one of the following relationships (A) and (B) is satisfied in the functional layers.
(A) y in the hole-transporting layer 108 and the electron-transporting layer 104 are each greater than y in the emission layer 106.
(B) z in the hole-transporting layer 108 and the electron-transporting layer 104 are each smaller than z in the emission layer 106.

The relationship (A) means that both the hole-transporting layer 108 and the electron-transporting layer 104 have a higher aluminum composition compared with the emission layer 106. In contrast, the relationship (B) means that both the hole-transporting layer 108 and the electron-transporting layer 104 have a lower gallium composition than the emission layer 106. Note that y in the hole-transporting layer 108 and the electron-transporting layer 104 may be the same as each other, or one may be greater than the other. Similarly, z in the hole-transporting layer 108 and the electron-transporting layer 104 may be the same as each other, or one may be larger than the other.

It is possible to structure the light-emitting element 100 in which the band gaps of the hole-transporting layer 108 and the electron-transporting layer 104 are both larger than that of the emission layer 106 by satisfying the relationships (A) and (B). Therefore, energy transfer from the emission layer 106 to the hole-transporting layer 108 and/or the electron-transporting layer 104 is suppressed, and the emission obtained in the emission layer 106 can be efficiently extracted.

When the light-emitting element 100 includes the hole-injection layer 110, the light-emitting element 100 is configured to further satisfy the following relationships (C) and (D).
(C) y in the hole-injection layer is less than y in the hole-transporting layer and equal to or greater than y in the emission layer.
(D) z in the hole-injection layer is greater than z in the hole-transporting layer and equal to or less than z in the emission layer.

The relationship (C) means that the composition of aluminum in the hole-injection layer 110 is less than that of the hole-transporting layer 108 and equal to or greater than that of the emission layer 106. In contrast, the relationship (D) means that the composition of gallium in the hole-injection layer 110 is greater than that of the hole-transporting layer 108 and equal to or less than that of the emission layer 106. Thus, the composition of aluminum and/or gallium may be identical to each other between the hole-injection layer 110 and the emission layer 106.

When the relationships (C) and (D) are satisfied, the light-emitting element 100 can be configured so that the band gap of the hole-injection layer 110 is smaller than that of the hole-transporting layer 108 and equal to or greater than that of the emission layer 106. The aforementioned energy transfer is suppressed, and the increase in the hole-injection barrier from the anode 112 to the functional layers can be suppressed.

When the light-emitting element 100 includes the electron-injection layer 102, the light-emitting element 100 is configured to further satisfy the following relationships (E) and (F).
(E) y in the electron-injection layer is less than y in the electron-transporting layer and equal to or greater than y in the emission layer.
(F) z in the electron-injection layer is greater than z in the electron-transporting layer and equal to or less than z in the emission layer.

The relationship (E) means that the composition of aluminum in the electron-injection layer 102 is less than that of the electron-transporting layer 104 and equal to or greater than that of the emission layer 106. In contrast, the relationship (F) means that the composition of gallium in the electron-injection layer 102 is greater than that of the electron-transporting layer 104 and equal to or less than that of the emission layer 106. Thus, the composition of aluminum and/or gallium may be identical to each other between the electron injecting layer 102 and the emitting layer 106. Note that y in the hole-injection layer 110 and the electron-injection layer 102 may be identical to each other, or one may be larger than the other. Similarly, z in the hole-injection layer 110 and the electron-injection layer 102 may be identical to each other, or one may be larger than the other.

It is possible to configure the light-emitting element 100 in which the band gap of the electron-injection layer 102 is smaller than that of the electron-transporting layer 104 and is equal to or greater than that of the emission layer 106 by satisfying the relationships (E) and (F). As a result, the aforementioned energy transfer can be suppressed, and the increase in the electron injection barrier from the cathode 114 to the functional layer can be suppressed.

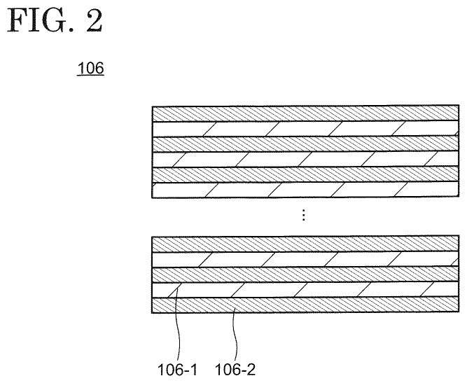

Note that, when at least one of the functional layers is composed of a plurality of layers, the compositions of the compound semiconductors are determined so that the aforementioned relationships (A) to (F) are satisfied for the plurality of layers in each functional layer. For example, when the emission layer 106 has an alternating stacked structure (quantum well structure) of a plurality of layers with different band gaps (a plurality of low band-gap layers 106-1 and a plurality of high band-gap layers 106-2) as shown in FIG. 2, the compositions of the compound semiconductors are determined so that both the low band-gap layers 106-1 and the high band-gap layers 106-2 satisfy the aforementioned relationships (A) to (F). In addition, the emission layer 106 is configured so that the layer in contact with the electron-transporting layer 104 and the layer in contact with the hole-transporting layer 108 are both high band-gap layers 106-2.

As described above, the emission layer 106 also includes a compound semiconductor represented by the composition formula of InₓAl_{y}Ga_{z}N. Therefore, the low band-gap layer 106-1 and the high band-gap layer 106-2 are configured so that the composition y of Al in the high band-gap layer 106-2 is greater than that in the low band-bap layer 106-1 and z in the high band-gap layer 106-2 is less than z in the low band-gap layer 106-1 in order to create a band gap difference between the low band-gap layer 106-1 and the high band-gap layer 106-2.

Furthermore, the compound semiconductor included in each functional layer is preferably selected so that the band gap thereof is equal to or greater than 1.5 eV and equal to or less than 3.5 eV. This selection allows the lattice constants of the compound semiconductors included in the functional layers to fall within a certain range (e.g., equal to or greater than 0.327 nm and equal to or less than 0.344 nm) and the deviation (difference) in the lattice constants between the functional layers to be reduced. As a result, high crystallinity can be obtained throughout the entire light-emitting element 100. Hence, there are extremely few crystal defects, and a decrease in lifetime and a shift of emission color caused by the crystal defects are prevented. Moreover, when 0<y, that is, when Al is included in all of the functional layers, the refractive index of each functional layer is relatively low, and a difference in refractive index between adjacent functional layers is reduced. Therefore, total reflection of the light from the emission layer 106 between adjacent functional layers can be suppressed, resulting in a high extraction efficiency. This feature contributes to an increase in the efficiency (current efficiency) of the light-emitting element 100.

### (3) Modified Examples

As a modified example, the light-emitting element 100 may be configured so that all of the functional layers do not contain gallium. That is, z may be 0 in each functional layer. In this case, the composition in which y=0 is eliminated, and 0<y<1. In other words, any functional layer contains a compound semiconductor represented by a composition of InₓAl_{y}N, where x+y=1±0.05, 0<x<1, and 0<y<1. Thus, each functional layer does not contain Ga but contains indium, aluminum, and nitrogen. In this case, the compound semiconductor of each functional layer is selected so that the above relationship (A) is satisfied. When the light-emitting element 100 includes the hole-injection layer 110 and the electron-injection layer 102, the compound semiconductor of each functional layer is selected so as to satisfy the aforementioned relationships (C) and (E), respectively.

In this modified example, the compound semiconductor included in each functional layer is preferred to be selected so that the band gap thereof is equal to or greater than 1.5 eV and equal to or less than 3.5 eV. This selection allows the lattice constant of the compound semiconductor included in each functional layer to fall within a certain range (e.g., equal to or greater than 0.327 nm and equal to or less than 0.344 nm), by which the differences in lattice constants between the functional layers can be reduced, and high crystallinity can be obtained throughout the light-emitting element 100. In addition, the refractive index of each functional layer is relatively small, and the difference in refractive index between adjacent functional layers is reduced. As a result, the total reflection of the light obtained in the emission layer 106 between adjacent functional layers can be suppressed, resulting in a high extraction efficiency. This feature contributes to an increase in the current efficiency of the light-emitting element 100.

### (4) Other Components

### (a) Buffer Layer

The light-emitting element 100 may further have a buffer layer 126 over the substrate 120 (FIG. 1A, FIG. 1B). In this case, the electron-transporting layer 104 or the hole-transporting layer 108 is located between the buffer layer 126 and the emission layer 106. When the light-emitting element 100 has the structure shown in FIG. 1A, i.e., when the electron-transporting layer 104, the emission layer 106, and the hole-transporting layer 108 are stacked in order from the substrate 120 side, the buffer layer 126 is located between the substrate 120 and the electron-transporting layer 104. The buffer layer 126 may be in contact with the electron-transporting layer 104, and the buffer layer 126 is provided to be in contact with the electron-injection layer 102 when the electron-injection layer 102 is provided.

When the light-emitting element 100 has the structure shown in FIG. 1B, i.e., when the hole-transporting layer 108, the emission layer 106, and the electron-transporting layer 104 are stacked in order from the substrate 120 side, the buffer layer 126 is located between the substrate 120 and the hole-transporting layer 108. The buffer layer 126 may be in contact with the hole-transporting layer 108, and the buffer layer 126 is provided to be in contact with the hole-injection layer 110 when the hole-injection layer 110 is provided.

The buffer layer 126 is a film contributing to the promotion of crystallization of the functional layers disposed thereover and improving the adhesion between the functional layers and the substrate 120 to prevent deformation (warpage) of the substrate 120 under the manufacturing conditions of the light-emitting element 100, thereby preventing peeling and crack generation in each functional layer provided thereover. Therefore, the generation of crystal defects in each functional layer of the light-emitting element 100 can be effectively suppressed when the buffer layer 126 is used.

Specifically, the buffer layer 126 may include an insulating material or a conductive material having a hexagonal-most-dense structure, a face-centered cubic structure, or a structure equivalent thereto. Here, a structure equivalent to the hexagonal-most-dense structure or the face-centered cubic structure includes a crystal structure in which the c-axis is not orthogonal to the a-axis and the b-axis. Thus, in this structure, the buffer layer 126 is oriented in the (0001) direction, i.e., the c-axis direction with respect to the substrate 120. Moreover, the buffer layer 126 having a face-centered cubic structure or a structure equivalent thereto is oriented in the (111) direction with respect to the substrate 120. Therefore, the c-axis of the buffer layer 126 is oriented in a direction perpendicular or substantially perpendicular to the surface over which the buffer layer 126 is provided (the surface of the substrate 120 in the example shown in FIG. 1A and FIG. 1B). On the other hand, the compound semiconductor included in each functional layer of the light-emitting element 100 exists in a wurtzite-type structure and undergoes crystal growth in the c-axis direction to minimize its surface energy. Therefore, the formation of the functional layers containing compound semiconductors over the buffer layer 126 promotes the crystal growth of the functional layers in the c-axis direction, thereby improving the crystallinity of each functional layer.

The buffer layer 126 may include a metal nitride such as aluminum indium nitride, aluminum nitride, titanium nitride, and gallium nitride, a metal oxide such as zinc oxide, lithium niobate (LiNbO), BiLaTiO, SrFeO, BiFeO, BaFeO, ZnFeO, and PMnN-PZT, silicon, germanium, or basic calcium phosphate (bio-apatite). The use of these materials enables the formation of an insulating buffer layer 126. In particular, the use of aluminum indium nitride promotes more effective c-axis orientation of the functional layers because the lattice constant shift can be reduced between the buffer layer 126 and the functional layer in contact with the buffer layer 126. Alternatively, the buffer layer 126 may contain a metal such as titanium, aluminum, silver, nickel, copper, strontium, rhodium, palladium, iridium, platinum, and gold. Since the buffer layer 126 is conductive and functions as a wiring when a metal is included, the buffer layer 126 may be used as a wiring to supply a potential to the anode 112. Alternatively, although not illustrated, the buffer layer 126 may be used as the anode 112 in contact with the hole-injection layer 110 or the hole-transporting layer 108.

The buffer layer 126 may be formed using a CVD method or a sputtering method. In order to more effectively grow the functional layer in the c-axis direction, the surface of the buffer layer 126 preferably has a high degree of flatness. Specifically, the arithmetic mean roughness (Ra) of the surface of the buffer layer 126 is preferred to be smaller than 2.3 nm. The root mean square roughness (Rq) of the surface of the buffer layer 126 is preferred to be smaller than 2.9 nm. The thickness of the buffer layer 126 is preferred to be equal to or less than 50 nm to obtain high surface flatness, and the buffer layer 126 is formed with a thickness equal to or greater than 10 nm and equal to or less than 50 nm, for example. The buffer layer 126 may also have a single layer structure or a stacked-layer structure.

### (b) Overcoat and Undercoat

An overcoat 122 may be arranged over the substrate 120 so as to be in contact with the substrate 120. An undercoat 124 may also be arranged under the substrate 120 which is in contact with the substrate 120. The overcoat 122 and the undercoat 124 may be configured as a single film or a laminate of a plurality of films containing a silicon-containing inorganic compound such as silicon oxide and silicon nitride or an aluminum-containing inorganic compound such as aluminum nitride and aluminum oxide. The formation of the overcoat 122 and/or the undercoat 124 prevents the diffusion of impurities such as alkali metal ions contained in the substrate 120. Furthermore, the undercoat 124 and the overcoat 122 suppress the elimination of impurities such as water from the substrate 120 under the conditions during the manufacture of the light-emitting element 100 to prevent impurities from entering the functional layers, and also prevent warpage of the substrate 120 due to the difference in thermal expansion coefficient between the substrate 120 and the functional layers or between the substrate 120 and the buffer layer 126. Hence, it is preferable to configure the undercoat 124 and the overcoat 122 to have the coefficient of thermal expansion higher than 4.0×10⁻⁶/° C. and lower than 5.0×10⁻⁶/° C.

### (c) Protective Film

As an optional component, the light-emitting element 100 may have a protective film 130 covering a portion of the functional layers, the cathode 114, and the anode 112. As a material included in the protective film 130, a silicon-containing inorganic compound such as silicon nitride, silicon oxide, silicon oxynitride, and silicon nitride oxide and a polymer such as an acrylic resin, an epoxy resin, a polyimide, and a polyamide are represented. For example, a laminate having a structure in which a polymer is sandwiched between two silicon-containing inorganic compounds may be used as the protective film 130. The protective film 130 is provided with openings exposing portions of the cathode 114 and the anode 112, and electrical connections to the light-emitting element can be performed through these openings.

As described above, each functional layer included in the light-emitting element 100 according to an embodiment of the present invention includes the compound semiconductor represented by the composition formula of InₓAl_{y}Ga_{z}N, and certain limits are imposed on x, y, and z between the functional layers. Furthermore, the light-emitting element 100 is configured so that the aforementioned relationships (A) through (F) are satisfied as appropriate, and the compound semiconductor may be selected so that the band gap of each functional layer is equal to or greater than 1.5 eV and equal to or less than 3.5 eV. Hence, the difference in refractive index and lattice constant between the functional layers can be reduced, and as a result, high crystallinity can be realized throughout the light-emitting element 100 and high extraction efficiency can be obtained. Therefore, implementation of an embodiment of the present invention enables the production of a light-emitting element with high emission efficiency and high reliability.

### 2. Manufacturing Method of Light-Emitting Element

Hereinafter, a manufacturing method of the light-emitting element 100 will be described using the configuration shown in FIG. 1A as an example. Since the undercoat 124, the overcoat 122, and the buffer layer 126 can be formed by applying known materials and methods, a detailed description is omitted. In brief, the undercoat 124 and the overcoat 122 may be formed over the substrate 120 by applying a sputtering method or a chemical vapor deposition (CVD) method as appropriate. The buffer layer 126 may be formed over the substrate 120 either directly or through the overcoat 122 using a sputtering method, a CVD method, an evaporation method, or the like as appropriate. After forming the buffer layer 126, annealing may be performed to promote crystallization to increase the density of the buffer layer 126. The temperature at this time may be selected as appropriate from a range equal to or higher than 500° C. and equal to or lower than 700° C., for example. Since the overcoat 122, the undercoat 124, and the buffer layer 126 are optional, one or all of these components may not be formed.

### (1) Formation of Functional Layer

The functional layers are formed so that the emission layer 106 is sandwiched between the hole-transporting layer 108 and the electron-transporting layer 104. When the light-emitting element 100 has the electron-injection layer 102 and the hole-injection layer 110, the functional layers are formed so that the hole-transporting layer 108, the electron-transporting layer 104, and the emission layer 106 are sandwiched between the electron-injection layer 102 and the hole-injection layer 110. Therefore, the electron-injection layer 102, the electron-transporting layer 104, the emission layer 106, the hole-transporting layer 108, and the hole-injection layer 110 may be formed over the substrate 120 in this order, or the functional layers may be stacked in a reverse order with respect to this order.

Each functional layer structuring the light-emitting element 100 is formed with a sputtering method. Therefore, the high temperature required for epitaxial growth of compound semiconductors by the CVD method is not required, and each functional layer can be formed at a temperature equal to or lower than the strain point of the amorphous glass substrate, for example.

(a) In Case Where 0<y<1 and 0<z<1

When the composition of the compound semiconductor in the functional layer satisfies 0<y and 0<z, that is, when the functional layer contains aluminum, indium, and gallium, the functional layer may be formed with reactive co-sputtering of an aluminum (Al) target, an indium (In) target, or an aluminum-indium (AlIn) target and a gallium nitride (GaN) target or a gallium (Ga) target using nitrogen gas or the like as a reactive gas. Alternatively, the functional layer may be formed with reactive co-sputtering using an aluminum-indium (AlIn) target as well as a gallium nitride (GaN) target or a gallium (Ga) target. In the case of using a gallium (Ga) target, nitrogen radical irradiation may be performed on the formed functional layer. Alternatively, the functional layer may be formed with reactive co-sputtering using an indium nitride (InN) target or an aluminum nitride-indium (AlInN) target and a gallium nitride (GaN) target. Alternatively, the functional layer may be formed with reactive sputtering of an aluminum-indium-gallium (AlInGa) target using nitrogen gas as a reactive gas. In this case, an aluminum-indium (AlIn) target may be further used in combination for co-sputtering. Alternatively, the functional layer may be formed by sputtering an aluminum-indium-gallium nitride (AlInGaN) target using argon gas as a sputtering gas. Even in this case, co-sputtering may be performed with an aluminum-indium-nitride (AlInN) target in combination, for example. The aluminum-indium-gallium (AlInGaN) target may be formed, for example, by injecting molten aluminum and indium into voids of a gallium nitride (GaN) target. When the functional layer contains a dopant, a corresponding target containing the dopant may be used.

When using a target consisting of a single metal or a single metal nitride (i.e., aluminum (Al) target, indium (In) target, gallium nitride (GaN) target, indium nitride (InN) target), a voltage between the target and the substrate 120 may be controlled to control the amount of materials ejected from each target, thereby controlling the composition of the functional layer. When using a target consisting of a plurality of metals or a target consisting of a plurality of metal nitrides (i.e., aluminum-indium (AlIn) target, aluminum-indium nitride (AlInN) target, aluminum-indium-gallium (AlInGa) target, aluminum-indium-gallium nitride (AlInGaN) target), the composition of each functional layer can be controlled by adjusting the composition of these targets.

(b) In The Case Where 0<y<1 and z=0

When the composition of the compound semiconductor in the functional layer satisfies 0<y<1 and z=0, that is, when the functional layer includes aluminum and indium but does not include gallium, the functional layer may be formed with reactive co-sputtering of an aluminum (Al) target and an indium (In) target using nitrogen gas or the like as a reactive gas. Alternatively, the functional layer may be formed with reactive sputtering of an aluminum-indium (AlIn) target using nitrogen as a reactive gas or with sputtering of an aluminum-indium nitride (AlInN) target using argon gas. Similar to the case of z≠0, when the functional layer contains a dopant, a corresponding target containing a dopant may be used. When a target consisting of a single metal or a single metal nitride is used, the composition of the functional layer may be controlled by controlling the voltage between the target and the substrate 120. When a target consisting of a plurality of metals or a plurality of metal nitrides is used, the composition of each functional layer may be controlled by adjusting the composition of these targets.

(c) In The Case Where y=0 and 0<z

When the composition of the compound semiconductor in the functional layer satisfies y=0 and 0<z, that is, when the functional layer contains indium and gallium but does not contain aluminum, an indium (In) target or an indium nitride (InN) target and a gallium nitride target (GaN) are used, and the functional layer may be formed with reactive co-sputtering using nitrogen gas or the like as a reactive gas or with co-sputtering using argon gas. Similar to the case of z≠0, when the functional layer contains a dopant, a corresponding target containing a dopant may be used. The voltage between the target and the substrate 120 may also be adjusted to control the composition of the functional layer.

### (2) Anode and Cathode

As the anode 112, a thin film of a metal such as palladium and gold, an alloy of these metals, or a conductive oxide transmitting visible light such as indium-tin mixed oxide (ITO) and indium-zinc mixed oxide (IZO) may be used, for example. As a cathode, a metal such as aluminum, titanium, gold, silver, and indium or an alloy of these metals may be used. Both the anode 112 and the cathode 114 may have a single-layer structure or a laminate of a plurality of films having different compositions. The anode 112 and the cathode 114 may be formed by applying a sputtering method, an evaporation method, or the like.

### (3) Protective Film

The protective film 130, which is an optional component, may also be formed using a CVD method or a sputtering method, for example. When a polymer is included, the protective film 130 may be formed using an ink-jet method, a spin-coating method, an evaporation method, or the like. For example, a film including a silicon-containing inorganic compound may be formed with a sputtering method or a CVD method, a film including a polymer may be formed thereover using an ink-jet method, a spin-coating method, or an evaporation method, and a film containing a silicon-containing inorganic compound may be further formed thereover with a sputtering method or a CVD method. The openings may be formed using photolithography as appropriate.

As described above, each functional layer included in the light-emitting element 100 can be formed with a sputtering method. Therefore, epitaxial growth of compound semiconductors with a CVD method is not required, and therefore, it is not necessary to apply the high temperature process required for epitaxial growth. Hence, not only single-crystal substrates such as single-crystal silicon substrates, but also substrates containing amorphous glass can be used as the substrates 120. In addition, while a CVD method tends to segregate indium, the sputtering method is able to suppress the segregation of certain elements because it is a non-equilibrium process. Therefore, the composition of the compound semiconductor in each functional layer is almost uniform, which also contributes to the high crystallinity of the functional layers. In addition, the functional layers can be formed without using a gallium nitride (GaN) target with a relatively high oxygen content, depending on the composition of the compound semiconductor. Therefore, the functional layer with high purity and crystallinity can be formed, and the reliability and characteristics of the light-emitting element 100 can be improved.

### Second Embodiment

In this embodiment, a display device 200 having the light-emitting element 100 described in the First Embodiment is explained. An explanation of the structures the same as or similar to those described in the First Embodiment may be omitted.

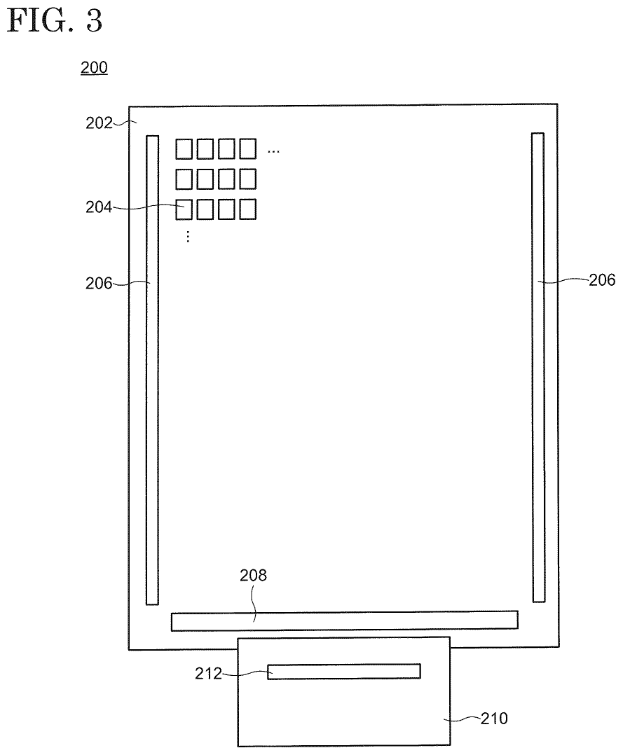

FIG. 3 shows a schematic top view of the display device 200. The display device 200 has a substrate 202. A variety of patterned thin films of insulators, conductors, and semiconductors is stacked over the substrate 202, by which a plurality of pixels 204, driver circuits (scanning-line driver circuit 206, signal-line driver circuit 208), and a variety of wirings (not illustrated) electrically connecting these components are fabricated. The plurality of pixels 204 is arranged in a matrix shape. A single region surrounding all of the pixels 204 is a display region, while the area outside the display region is called a peripheral region or a frame region. The plurality of wirings extends to one side of the substrate 202 from the driver circuits and is exposed at an edge of the substrate 202 to form a plurality of terminals (not illustrated). The plurality of terminals is electrically connected to a connector 210 such as a flexible printed circuit (FPC) board, by which power and a variety of signals are supplied from an external circuit which is not illustrated to the driver circuits via the connector 210. Instead of or together with the signal-line driver circuit 208, a driver IC 212 with integrated circuits formed over a semiconductor substrate may be mounted on the substrate 202 or the connector 210.

The plurality of pixels 204 is connected to the scanning-line driver circuits 206 and the signal-line driver circuit 208. The scanning-line driver circuits 206 and the signal-line driver circuit 208 generate signals for displaying images (video signals, gate signals, and initialization signals, and the like) on the basis of the signals supplied from the external circuit and supply these signals to the plurality of pixels 204 together with power, by which the plurality of pixels 204 is controlled and images are displayed on the display region.

In each pixel 204, a pixel circuit connected to the scanning-line driver circuit 206 and the signal-line driver circuit 208 is formed, and the light-emitting element 100 electrically connected to the pixel circuit is arranged. The configuration of the pixel circuit may be arbitrarily determined, and the pixel circuit is formed by combining one or a plurality of transistors and one or a plurality of capacitor elements as appropriate. The pixel circuit is operated by the signals supplied from the driver circuits, thereby controlling the light-emitting element 100.

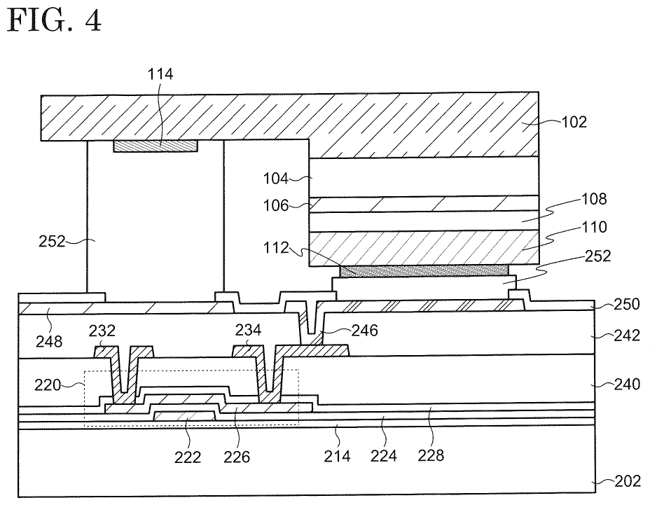

An example of the pixel 204 is shown in the schematic cross-sectional view of FIG. 4. Although one transistor 220 is illustrated as the pixel circuit in FIG. 4, each pixel circuit may include a plurality of transistors and may further include one or a plurality of capacitor elements as described above. The pixel circuit including the transistor 220 is provided over the substrate 202 directly or through an overcoat 214 which is an optional component. The transistor 220 shown in FIG. 4 is composed of a gate electrode 222, a gate insulating film 224 over the gate electrode 222, a semiconductor film 226 over the gate insulating film 224, a first interlayer insulating film 228 and a second interlayer insulating film 240 over the semiconductor film 226, and a first terminal 232 and a second terminal 234 electrically connected to the semiconductor film 226 through openings formed in the first interlayer insulating film 228 and the second interlayer insulating film 240, and the like. . Although the transistor 220 is a so-called bottom-gate type transistor, there is no restriction on the structure of the transistor 220, and the transistor 220 may be a top-gate type transistor or a transistor having a pair of gate electrodes over and under the semiconductor film 226.

A leveling film 242 may be provided over the second interlayer insulating film 240, and a pixel electrode 246 over the leveling film 242 is electrically connected to the second terminal 234 through an opening formed in the leveling film 242. A common electrode 248 supplied with a constant potential is disposed over the leveling film 242. The display device 200 may further have a protective insulating film 250 covering the edges of the pixel electrode 246 and the common electrode 248. Since these components can be formed by applying known materials and deposition methods as appropriate, a detailed description is omitted.

The light-emitting element 100 is provided in each pixel 204. That is, each pixel 204 is fabricated by transferring the light-emitting element 100 formed on the substrate 120 to the pixel 204. Thus, when the light-emitting element 100 has the structure shown in FIG. 1A, the cathode 114 and the anode 112 are electrically connected to the common electrode 248 and pixel electrode 246, respectively, through bumps 252 functioning as a conductive adhesive. The bump 252 is, for example, an alloy containing a metal such as silver and tin. Although not illustrated, the light-emitting element 100 may include the buffer layer 126 over the electron-injection layer 102.

As described in the First Embodiment, in the light-emitting element 100, the difference in refractive index and lattice constant between the functional layers can be reduced due to the composition of the compound semiconductors included in the functional layers. As a result, high crystallinity can be obtained with few lattice defects throughout the light-emitting element 100, and high extraction efficiency can be realized. Therefore, implementation of the present embodiment enables the production of display devices exhibiting low power consumption and high reliability.

### Third Embodiment

In this embodiment, a lighting device 300 having the light-emitting element 100 described in the First Embodiment is explained. An explanation of the structures the same as or similar to those described in the First and Second Embodiments may be omitted.

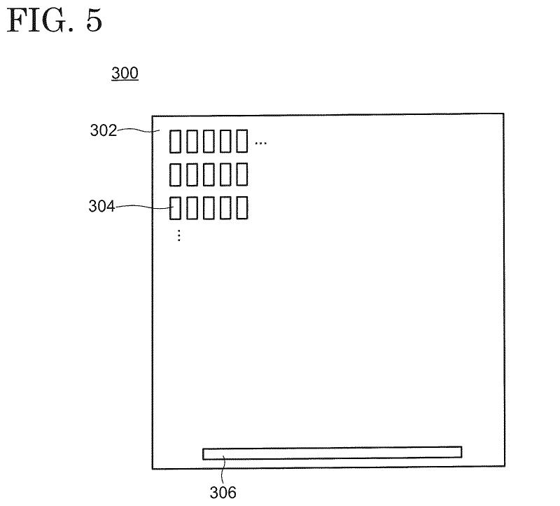

A schematic top view of the lighting device 300 according to the present embodiment is shown in FIG. 5. As shown in FIG. 5, the lighting device 300 has a substrate 302 and one or a plurality of light sources 304 over the substrate 302. The arrangement of the plurality of light sources 304 is arbitrarily determined, and the plurality of light sources 304 may be arranged in a matrix shape as shown in FIG. 5 or on a single line or concentric circles. Alternatively, the plurality of light sources 304 may be randomly arranged. The shape of the substrate 302 is also arbitrary and may be determined as appropriate in consideration of the location where the lighting device 300 is installed and the design of the lighting device 300. For example, the planar shape of the substrate 302 may be a circular shape, an oval shape, or a polygonal shape including a square and a rectangle.

A driver circuit 306 connected to each light source 304 is provided over the substrate 302, and the driver circuit 306 is electrically connected to the light source 304 with a wiring which is not illustrated. The driver circuit 306 is configured to receive control commands by wired or wireless means from a control device which is not illustrated and to control the light sources 304 according to the control commands.

One or a plurality of the light-emitting elements 100 described in the First Embodiment is arranged in each light source 304. For example, red-emissive, green-emissive, and blue-emissive light-emitting elements 100 different in structure of the emission layer 106 from one another may be arranged in each light source 304, or one or a plurality of light-emitting elements 100 with the same emission color may be arranged in each light source 304. A lighting device capable of providing light of a variety of colors can be produced by utilizing the red-emissive, green-emissive, and blue-emissive light-emitting elements 100.

As described in the First Embodiment, in the light-emitting element 100, the difference in refractive index and lattice constant between the functional layers can be reduced due to the composition of the compound semiconductors included in the functional layers. As a result, there is few lattice defects, and high crystallinity can be obtained throughout the light-emitting element 100, by which high extraction efficiency can be obtained. Therefore, implementation of the present embodiment enables the production of a lighting device exhibiting low power consumption and high reliability.

The aforementioned modes described as the embodiments of the present invention can be implemented by appropriately combining with each other as long as no contradiction is caused. Furthermore, any mode which is realized by persons ordinarily skilled in the art through the appropriate combination, addition, deletion, or design change of elements or through the addition, deletion, or condition change of a process according to the display device of each embodiment is included in the scope of the present invention as long as they possess the concept of the present invention.

It is understood that another effect different from that provided by each of the aforementioned embodiments is achieved by the present invention if the effect is obvious from the description in the specification.

What is claimed is:

1. A light-emitting element comprising:
a hole-transporting layer;
an electron-transporting layer;
an emission layer sandwiched by the hole-transporting layer and the electron-transporting layer; and
an anode and a cathode electrically connected to the hole-transporting layer and the electron-transporting layer, respectively,
wherein the hole-transporting layer, the electron-transporting layer, and the emission layer each include a compound semiconductor expressed by a composition formula of InₓAl_{y}Ga_{z}N,
x+y+z=1±0.05, 0<x<1, 0≤y<1, and 0≤z<1,
0<z when y=0, and 0<y when z=0, and
at least one of following relationships is satisfied:
(1) y in the hole-transporting layer and the electron-transporting layer are each larger than y in the emission layer; and
(2) z in the hole-transporting layer and the electron-transporting layer are each smaller than z in the emission layer.

2. The light-emitting element according to claim 1,
wherein a band gap of the compound semiconductor is equal to or greater than 1.5 eV and equal to or less than 3.5 eV.

3. The light-emitting element according to claim 1,
wherein a lattice constant of the compound semiconductor is equal to or greater than 0.327 nm and equal to or less than 0.337 nm.

4. The light-emitting element according to claim 1,
wherein the hole-transporting layer and the electron-transporting layer respectively include a p-type dopant and an n-type dopant.

5. The light-emitting element according to claim 1,
wherein the emission layer has a quantum well structure.

6. The light-emitting element according to claim 1, further comprising a hole-injection layer located between the hole-transporting layer and the anode and including the compound semiconductor,
wherein at least one of following relationships is satisfied:
(3) y in the hole-injection layer is smaller than y in the hole transporting layer and equal to or greater than y in the emission layer; and
(4) z in the hole-injection layer is greater than z in the hole-transporting layer and equal to or less than z in the emission layer.

7. The light-emitting element according to claim 1, further comprising an electron-injection layer located between the electron-transporting layer and the cathode and including the compound semiconductor,
wherein at least one of the following relationships is satisfied:
(5) y in the electron-injection layer is less than y in the electron-transporting layer and equal to or greater than y in the emission layer; and
(6) z in the electron-injection layer is greater than z in the electron-transporting layer and equal to or less than z in the emission layer.

8. The light-emitting element according to claim 1, wherein z=0 and 0<y<1.

9. The light-emitting element according to claim 8,
wherein a lattice constant of the compound semiconductor is equal to or greater than 0.327 nm and equal to or less than 0.334 nm.

10. The light-emitting element according to claim 1, further comprising a buffer layer,
wherein the electron-transporting layer or the hole-transporting layer is located between the buffer layer and the emission layer, and
the buffer layer includes a material selected from aluminum indium nitride, aluminum nitride, aluminum oxide, gallium nitride, zinc oxide, silicon, germanium, titanium, aluminum, silver, nickel, and copper.

11. A manufacturing method of a light-emitting element comprising:
forming a hole-transporting layer, an electron-transporting layer, and an emission layer sandwiched by the hole-transporting layer and the electron-transporting layer with a sputtering method; and
forming an anode and a cathode electrically connected to the hole-transporting layer and the electron-transporting layer, respectively,
wherein the hole-transporting layer, the electron-transporting layer, and the emission layer each include a compound semiconductor expressed by a composition formula of InₓAl_{y}Ga_{z}N,
x+y+z=1±0.05, 0<x<1, 0≤y<1, and 0≤z<1,
0<z when y=0, and 0<y when z=0, and
at least one of following relationships is satisfied:
(1) y in the hole-transporting layer and the electron-transporting layer are each larger than y in the emission layer; and
(2) z in the hole-transporting layer and the electron-transporting layer are each smaller than z in the emission layer.

12. The manufacturing method according to claim 11,
wherein a band gap of the compound semiconductor is equal to or greater than 1.5 eV and equal to or less than 3.5 eV.

13. The manufacturing method according to claim 11,
wherein a lattice constant of the compound semiconductor is equal to or greater than 0.327 nm and equal to or less than 0.337 nm.

14. The manufacturing method according to claim 11,
wherein the hole-transporting layer and the electron-transporting layer respectively include a p-type dopant and an n-type dopant.

15. The manufacturing method according to claim 11,
wherein the emission layer has a quantum well structure.

16. The manufacturing method according to claim 11, further comprising forming a hole-injection layer including the compound semiconductor so as to be sandwiched by the anode and the hole-transporting layer,
wherein at least one of following relationships is satisfied:
(3) y in the hole-injection layer is smaller than y in the hole-transporting layer and equal to or greater than y in the emission layer; and
(4) z in the hole-injection layer is greater than z in the hole-transporting layer and equal to or less than z in the emission layer.

17. The manufacturing method according to claim 11, further comprising forming an electron-injection layer including the compound semiconductor with a sputtering method so as to be sandwiched by the cathode and the electron-transporting layer,
wherein at least one of the following relationships is satisfied:
(5) y in the electron-injection layer is less than y in the electron-transporting layer and equal to or greater than y in the emission layer; and
(6) z in the electron-injection layer is greater than z in the electron-transporting layer and equal to or less than z in the emission layer.

18. The manufacturing method according to claim 11,
wherein z=0 and 0<y<1.

19. The manufacturing method according to claim 18,
wherein a lattice constant of the compound semiconductor is equal to or greater than 0.327 nm and equal to or less than 0.334 nm.

20. The light-emitting element according to claim 1, further comprising forming a buffer layer before forming the hole-transporting layer, the electron-transporting layer, and the emission layer,
wherein the buffer layer includes a material selected from aluminum indium nitride, aluminum nitride, aluminum oxide, gallium nitride, zinc oxide, silicon, germanium, titanium, aluminum, silver, nickel, and copper.
